(19) United States
(12) Patent Application Publication
(10) Pub. No.: US 2018/0217561 A1
(43) Pub. Date: Aug. 2, 2018

(54) SOLAR CELL DEVICE AND METHOD FOR PRODUCING THE SAME

(71) Applicant: SEIKO EPSON CORPORATION, Tokyo (JP)

(72) Inventors: Tetsuya Isshiki, Shiojiri (JP); Xiaoxing Wang, Chino (JP)

(21) Appl. No.: 15/873,439

(22) Filed: Jan. 17, 2018

(30) Foreign Application Priority Data
Jan. 30, 2017 (JP) 2017-014801

(51) Int. Cl. G04C 10/02; H01L 31/0224; G04G 9/00

(52) U.S. Cl. CPC G04C 10/02; Y10S 136/291; G04G 9/0088; H01L 31/022425

(57) ABSTRACT

A solar cell device includes an information display, a protective substrate that protects an information display surface of the information display, and a photoelectric conversion element. The photoelectric conversion element is disposed on a surface of the protective substrate. The surface faces the information display surface of the information display. The photoelectric conversion element includes a first electrode including a transparent electrode material, a second electrode including a transparent electrode material, a photoelectric conversion layer disposed between the first electrode and the second electrode and including an organic-inorganic perovskite compound, an electron transport layer, disposed between the first electrode and the photoelectric conversion layer, and a hole transport layer, disposed between the photoelectric conversion layer and the second electrode.

This application claims priority under 35 U.S.C. § 119 to Japanese Patent Application No. 2017-014801 filed on Jan. 30, 2017, the entire disclosure of which is expressly incorporated by reference herein.

### BACKGROUND

1. Technical Field

The present invention relates to a solar cell device and a method for producing the same.

2. Related Art

Incorporation of a solar cell into an electronic apparatus, such as a timepiece, is a known technology. For example, JP-A-2015-90885 discloses a watch including an amorphous silicon (Si) solar cell. In the structure, the solar cell is disposed under the clock face. With the watch disclosed in JP-A-2015-90885, however, the clock face needs to be designed not to interfere with the functions of the solar cell, and in addition, the color of amorphous Si, black, limits the decoration of the clock face. Furthermore, sunlight enters through the clock face, and this reduces the power generation efficiency. Thus, in the structure, a light scattering layer and a light reflective layer need to be disposed on the solar cell to compensate for the reduction in the power generation efficiency. As a result, the design properties of the clock face may be adversely affected.

In view of this, JP-A-2001-267604, for example, proposes a watch in which, while an amorphous Si solar cell is used as with JP-A-2015-90885, the solar cell is disposed over the clock face. In the watch disclosed in JP-A-2001-267604, the solar cell is designed to be narrow so as to be pseudo-transparent, and also, a transparent substrate is used to increase the transparency of the solar cell. This configuration inhibits a reduction in power generation efficiency even when the solar cell is disposed over the clock face.

Furthermore, JP-A-2002-107469 discloses a watch in which, as with JP-A-2001-267604, the solar cell is narrow to enable flexibility in clock face design and the back cover is including transparent glass. This configuration provides a watch of novel design.

However, although the watches disclosed in JP-A-2001-267604 and JP-A-2002-107469 are made to be pseudo-transparent by reducing the width of the solar cells, the color is substantially black because the solar cells incorporated therein are including amorphous Si. Thus, since the original color cannot be removed completely, a sense of high quality, particularly regarding high-quality watches, will be lost. Furthermore, in order to exploit the characteristics of the solar cell, it is desirable that the cell area be large. However, narrow solar cells have a small area and therefore pose a problem in that they have decreased power generation efficiency.

### SUMMARY

An advantage of some aspects of the invention is that a solar cell device having high decorative design flexibility and a method for producing the same are provided. According to a first aspect of the invention, a solar cell device is configured as follows. The solar cell device includes an information display, a protective substrate that protects an information display surface of the information display, and a photoelectric conversion element. The photoelectric conversion element is disposed on a surface of the protective substrate, the surface facing the information display surface of the information display. The photoelectric conversion element includes a first electrode including a transparent electrode material, a second electrode including a transparent electrode material, a photoelectric conversion layer disposed between the first electrode and the second electrode and including an organic-inorganic perovskite compound, an electron transport layer disposed between the first electrode and the photoelectric conversion layer, and a hole transport layer disposed between the photoelectric conversion layer and the second electrode. In the first aspect, the solar cell device has high decorative design flexibility.

In the first aspect, it is preferable that the organic-inorganic perovskite compound be a compound produced by a reaction between lead halide and organic ammonium halide. With this configuration, the resulting organic-inorganic perovskite compound has transparency and thus does not interfere with the decorative properties of the solar cell device.

Furthermore, it is preferable that the organic-inorganic perovskite compound be a compound selected from the group consisting of CH₃NH₃PbBr₃, CH₃NH₃PbBr₂Cl, CH₃NH₃PbCl₃, and CH₃NH₃PbBrCl₂. With this configuration, the resulting organic-inorganic perovskite compound has transparency with certainty and thus does not interfere with the decorative properties of the solar cell device.

Furthermore, the photoelectric conversion layer may include a colorless transparent organic-inorganic perovskite compound and a colored transparent organic-inorganic perovskite compound. With this configuration, operation on a wide range of wavelengths is achieved without interfering with the decorative properties of the solar cell device. As a result, the solar cell device has high photoelectric conversion efficiency and improved decorative properties.

Furthermore, it is preferable that the colorless transparent organic-inorganic perovskite compound be CH₃NH₃PbCl₃ and that the colored transparent organic-inorganic perovskite compound be a compound selected from the group consisting of CH₃NH₃PbBr₃, CH₃NH₃PbBr₂Cl, and CH₃NH₃PbBrCl₂. With this configuration, operation on a wide range of wavelengths is achieved without interfering with the decorative properties of the solar cell device. As a result, the solar cell device has higher photoelectric conversion efficiency and further improved decorative properties.

Furthermore, the transparent electrode material of the second electrode may be metal nanowires. With this configuration, the transparency of the organic-inorganic perovskite compound is maintained without impairing the function of the second electrode, and therefore the decorative properties of the solar cell device is not interfered with.

The first electrode may be disposed on the protective substrate. With this configuration, the solar cell device has good cost effectiveness and high decorative design flexibility.

According to a second aspect of the invention, a method for producing a solar cell device is as follows. The method includes forming a photoelectric conversion element by sequentially stacking, on a surface of a protective substrate, a first electrode, an electron transport layer, a photoelectric conversion layer, a hole transport layer, and a second electrode, the protective substrate protecting an information display surface of an information display. The first electrode includes a transparent electrode material and the second electrode includes a transparent electrode material. The photoelectric conversion layer includes an organic-inorganic perovskite compound produced by forming a layer of lead halide and a layer of organic ammonium halide and heating the layers. In the second aspect, a solar cell device having high decorative design flexibility is provided.

### BRIEF DESCRIPTION OF THE DRAWINGS

The invention will be described with reference to the accompanying drawings, wherein like numbers reference like elements.

FIG. 1 is a plan view illustrating an overall configuration of a watch.

FIG. 2 is a cross-sectional view taken along the line II-II in FIG. 1.

FIG. 3 is a cross-sectional view illustrating an example of a configuration of a photoelectric conversion element.

FIG. 4 is a cross-sectional view illustrating an example of production of the photoelectric conversion element.

FIG. 5 is a cross-sectional view illustrating the example of production of the photoelectric conversion element.

FIG. 6 is a cross-sectional view illustrating the example of production of the photoelectric conversion element.

FIG. 7 is a cross-sectional view illustrating the example of production of the photoelectric conversion element.

### DESCRIPTION OF EXEMPLARY EMBODIMENTS

Hereinafter, embodiments of the invention will be described with reference to the drawings. The descriptions below illustrate certain embodiments of the invention, and changes may be made thereto as desired without departing from the scope of the invention. X, Y, and Z represent three spatial axes orthogonal to one another. In this specification, the directions along the axes are designated as a first direction X (X direction), a second direction Y (Y direction), and a third direction Z (Z direction). In the drawings, the directions indicated by the arrows are designated as positive (+) directions and the directions opposite to the arrows are designated as minus (−) directions. The X direction and the Y direction are in-plane directions of each constituent element, and the Z direction is a thickness direction or a stacking direction of each constituent element.

In the drawings, the shapes, sizes, thicknesses, relative positional relationships, and other properties of the constituent elements may be exaggerated in order to better describe the invention. Furthermore, in this specification, the term “on” is not intended to limit the position of a constituent element to a position “directly on” another constituent element. For example, the phrases “first electrode on a substrate” and “electron transport layer on a first electrode” do not exclude configurations in which another constituent element is included between the substrate and the first electrode, or between the first electrode and the electron transport layer.

### FIRST EMBODIMENT

### Solar Cell Device

First, a solar powered watch (hereinafter referred to as a watch), which is an example of a solar cell device, will be described with reference to the drawings.

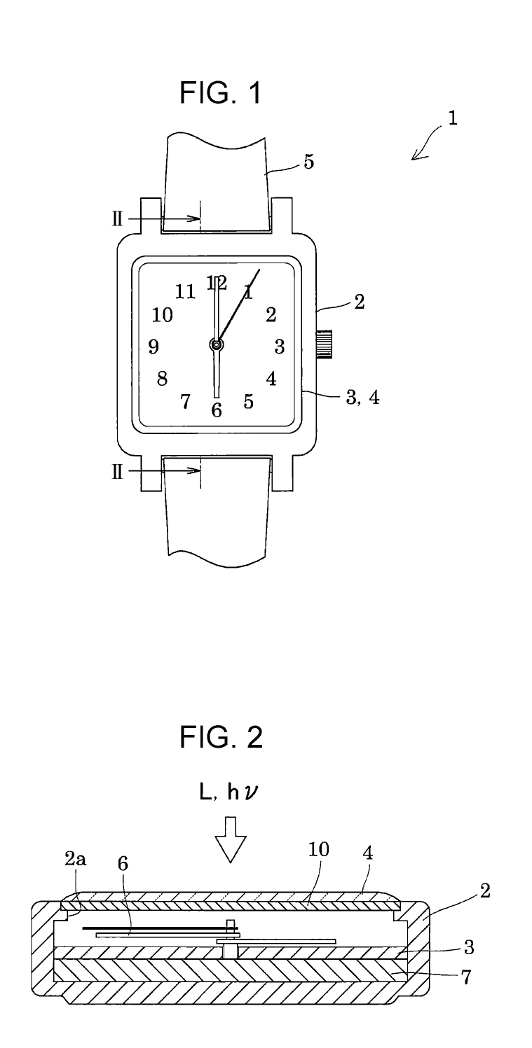

FIG. 1 is a plan view illustrating an overall configuration of the watch. As illustrated, a watch 1 includes an external case 2, a clock face 3, a cover glass 4, and a band 5. The clock face 3 is an information display for displaying information (in this embodiment, time). The cover glass 4 is a protective substrate for protecting the clock face 3. In the watch 1, a variety of components, such as a photoelectric conversion element 10 (see FIG. 2, for example), are housed within the external case 2. The photoelectric conversion element 10 will be described later. The band 5 is coupled to the external case 2. The external case 2 is attached to an arm of the user via the band 5. The watch 1 is a watch incorporating the photoelectric conversion element 10. Light L (light energy hv) (see FIG. 2) that enters the photoelectric conversion element 10 is converted into electrical energy to be used.

FIG. 2 is a cross-sectional view taken along line II-II in FIG. 1. As illustrated, the external case 2 includes an opening 2a, which is open to the exterior. The opening 2a is covered by the cover glass 4 and closed. The watch 1 includes hands 6, the clock face 3, and a movement 7 within the external case 2. The movement 7 drives the hands 6 in accordance with the time. The movement 7 includes a secondary battery (not illustrated) to store electricity generated by the photoelectric conversion element 10. Utilizing the light L entering from outside the external case 2, the photoelectric conversion element 10 converts the light energy hv to electrical energy to cause the movement 7 to operate. The photoelectric conversion element 10 is disposed on one side of the cover glass 4. The one side is the side closer to the surface (information display surface) of the clock face 3.

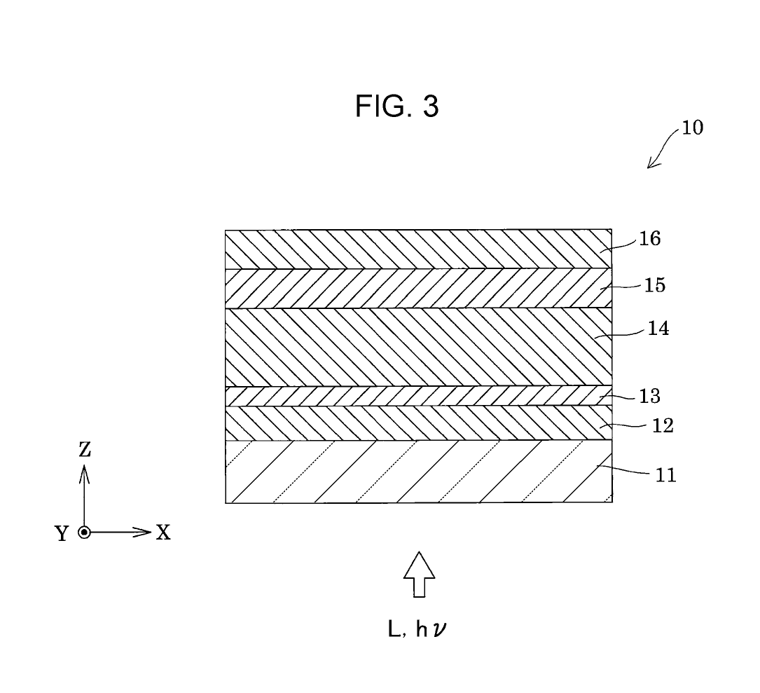

FIG. 3 is a cross-sectional view illustrating an example of a configuration of the photoelectric conversion element. As illustrated, the photoelectric conversion element 10 includes a substrate 11, a first electrode 12, which is disposed on the substrate 11, a second electrode 16, a photoelectric conversion layer 14, which is disposed between the first electrode 12 and the second electrode 16, an electron transport layer 13, which is disposed between the first electrode 12 and the photoelectric conversion layer 14, and a hole transport layer 15, which is disposed between the photoelectric conversion layer 14 and the second electrode 16. According to this embodiment, the photoelectric conversion element 10 is made up of the substrate 11, the first electrode 12, the electron transport layer 13, the photoelectric conversion element 14, the hole transport layer 15, and the second electrode 16, which are sequentially stacked. The photoelectric conversion element 10 may be made up of the substrate 11, the first electrode 12, the hole transport layer 15, the photoelectric conversion element 14, the electron transport layer 13, and the second electrode 16, which are sequentially stacked. In other configurations, the layers may be reduced or increased as necessary.

When the photoelectric conversion element 10, which is configured as described above, is irradiated with the light L (light energy hv) emitted in the +Z direction through the back side (the surface joined to the cover glass 4 in FIG. 2) of the substrate 11, an organic-inorganic perovskite compound (to be described later) of the photoelectric conversion layer 14 in the photoelectric conversion element 10 is excited to generate electrons and holes. Of these, the electrons migrate through the electron transport layer 13 into the first electrode 12 and migrate through an external circuit (not illustrated) into the second electrode 16 to be supplied to the hole transport layer 15. The organic-inorganic perovskite compound, which has lost electrons and been oxidized, receives electrons from the hole transport layer 15 to return to the ground state. The photoelectric conversion element 10 repeats this cycle to convert the light energy hv into electrical energy. The elements included in the photoelectric conversion element 10 will be described in detail below.

In the photoelectric conversion element 10, the substrate 11 is disposed on the side through which the light L (sunlight) enters. The substrate 11 is preferably a transparent substrate from the standpoint of the photoelectric conversion efficiency of the photoelectric conversion element 10. The material, shape, structure, thickness, hardness, and other properties of the substrate 11 may be selected as appropriate from among those of known substrates. Examples of the substrate that may be selected as appropriate include rigid substrates such as glass substrates (inorganic glass) and acrylic substrates, and flexible substrates such as film substrates. As used herein, the term “transparent” means substantially transparent and encompasses not only colorless transparent but also colored transparent and translucent.

In this embodiment, the photoelectric conversion element 10 is disposed on the one side of the cover glass 4, which is the side closer to the surface (information display surface) of the clock face 3, and joined to the cover glass 4 by a predetermined method. From the standpoint of light transmissive properties, the substrate 11 is preferably including the same transparent material as the material of the cover glass 4 and is thus, for example, preferably a glass substrate. In this case, there are no particular limitations on the thickness of the substrate 11, and the thickness may be appropriately determined as necessary. The process for joining the substrate 11 of the photoelectric conversion element 10 to the cover glass 4 is not particularly limited as long as the incidence of the light L (sunlight) is not interfered with. For example, an adhesive or the like may be used.

From the standpoint of simplification of the process and cost effectiveness, the cover glass 4 may be used as the substrate 11. In such a case, the first electrode 12, the electron transport layer 13, the photoelectric conversion layer 14, the hole transport layer 15, and the second electrode 16 are sequentially stacked on the cover glass 4 to form the photoelectric conversion element 10.

When a flexible substrate is used as the substrate 11, the flexible substrate may be a film of a resin. Examples of such a resin include: polyester-based resins, such as polyethylene terephthalate (PET), polyethylene naphthalate (PEN), and modified polyesters; polyolefin-based resins, such as polyethylene (PE), polypropylene (PP), polystyrene, and cyclic olefins; vinyl-based resins, such as polyvinyl chloride and polyvinylidene chloride; polyvinyl acetal-based resins, such as polyvinyl butyral (PVB); polyether ether ketone (PEEK) resins; polysulfone (PSF) resins, polyether sulfone (PES) resins, polycarbonate (PC) resins, polyamide resins, polyimide resins, acrylic resins, and triacetyl cellulose (TAC) resins. In addition to these resin films, examples of the resin film that can be used as the substrate 11 include fluorine (fluorocarbon)-based resin films, such as films of Teflon (registered trademark). In this case too, the film is preferably transparent, and there are no particular limitations on the thickness of the substrate 11.

In order to ensure wettability and adhesiveness of the coating liquid for forming the first electrode 12, the substrate 11 may be subjected to a surface treatment and/or may include an adhesion-promoting layer as necessary. For the surface treatment and adhesion-promoting layer, any known technique may be used. Examples of the surface treatment include surface activation treatments, such as corona discharge treatments, flame treatments, UV (ultraviolet) treatments, high frequency treatments, glow discharge treatments, active plasma treatments, and laser treatments. Examples of the material of the adhesion-promoting layer include polyester, polyamide, polyurethane, vinyl copolymers, butadiene copolymers, acrylic copolymers, vinylidene copolymers, and epoxy copolymers. It is preferable that the surface treatment and the adhesion-promoting layer also not interfere with the transparency of the substrate 11.

The first electrode 12 is disposed on the substrate 11. It is preferable that the first electrode 12 be disposed on an opposite surface of the substrate 11. The opposite surface is opposite to the surface through which the light L enters (the surface closer to the clock face 3 in FIG. 2). Furthermore, it is preferable that the first electrode 12 be a transparent electrode from the standpoint of photoelectric conversion efficiency of the photoelectric conversion element 10. The definition of the term “transparent” is as described above.

The material, shape, structure, thickness, electrical conductivity, and other properties of the first electrode 12 may be selected as appropriate from among those of known electrodes. The first electrode 12 may be a thin film or a stack of thin films. Examples of the thin film or films include those made of one or more transparent materials such as indium tin oxide (ITO) and fluorine tin oxide (FTC)). In addition, examples of the thin film or films include those including one or more electrically conductive metal oxides, such as tin oxide (SnO₂), indium zinc oxide (IZO), and zinc oxide (ZnO). The first electrode 12 may be a thin film including a polymeric material having high electrical conductivity. Examples of the polymeric material include polyacetylene-based materials, polypyrrole-based materials, polythiophene-based materials, and polyphenylenevinylene-based materials. Among these, transparent electrode materials, such as ITO and FTO, are preferable because they have electrical conductivity and do not interfere with the transparency of the substrate 11.

The average thickness of the first electrode 12 is not particularly limited, but preferably, ranges from greater than or equal to 0.1 mm to less than or equal to 5 mm. The surface resistance (also referred to as sheet resistance) of the first electrode 12 is preferably less than or equal to 50 Ω/□ (square), more preferably less than or equal to 20 Ω/□, still more preferably 10 Ω/□, and particularly preferably 5 Ω/□. It is preferable that the lower limit of the surface resistance of the first electrode 12 be as low as possible. Thus, although the lower limit need not be particularly specified, it is preferably greater than or equal to 0.01 Ω/□.

The electron transport layer 13 is disposed on the first electrode 12. In this embodiment, the electron transport layer 13 is disposed on the first electrode 12 and between the first electrode 12 and the photoelectric conversion layer 14, which will be described later. The electron transport layer 13 has the function of blocking the transport of the charges (holes) opposite to the charges (electrons) that the electron transport layer 13 mainly transports. That is, the electron transport layer 13 is configured to prevent migration of the holes to the first electrode 12 (anode) so that the electrons generated in the photoelectric conversion layer 14 can be efficiently migrated to the first electrode 12. If the electron transport layer 13 does not have a function of blocking transport of the holes, migration of the electrons and holes to the first electrode 12 via the electron transport layer 13 will occur, and as a result, deactivation due to recombination of the electrons and holes will occur. Thus, because of the function of blocking transport of holes as described above, the electron transport layer 13 inhibits deactivation due to recombination of the holes and electrons, and this enables efficient transport of the electrons to the first electrode 12.

Examples of the material for forming the electron transport layer 13 include electrically conductive polymers formed from a fullerene or a derivative thereof. Examples of the fullerene and the derivative include phenyl-C61-butyric acid methyl ester (PCBM), poly(9,9-di-n-octylfluorenyl-2,7-diyl), and C60 fullerenes. The examples of the material further include transparent materials such as titanium oxide (TiOₓ). In this embodiment, the material (electrically conductive polymer) for forming the hole transport layer 15, which will be described later, may be employed. In this embodiment, transparent materials such as TiOₓ are preferred because they are capable of transporting electrons and do not interfere with the transparency of the substrate 11. The average thickness of the electron transport layer 13 is not particularly limited, but preferably, is less than or equal to 1 μm, more preferably less than or equal to 100 nm, and particularly preferably ranges from greater than or equal to 20 nm to less than or equal to 60 nm.

The photoelectric conversion layer 14 is disposed between the first electrode 12 and the second electrode 16. In this embodiment, the photoelectric conversion layer 14 is disposed between the first electrode 12 and the second electrode 16 and on the electron transport layer 13. The photoelectric conversion layer 14 includes a compound of organic-inorganic perovskite structure (hereinafter referred to as organic-inorganic perovskite compound), which is a hybrid compound produced by a reaction between an organic compound and an inorganic compound. When the photoelectric conversion layer 14 is irradiated with light, photoexcitation occurs to generate an electromotive force. The average thickness of the photoelectric conversion layer 14 is not particularly limited, but preferably, ranges from greater than or equal to 150 nm to less than or equal to 400 nm, and particularly preferably ranges from greater than or equal to 150 nm to less than or equal to 300 nm.

The organic-inorganic perovskite compound is a superlattice structure including alternating inorganic and organic layers. In each of the inorganic layers, a divalent metal atom M is at the center in 6-fold coordination, surrounded by an octahedron of halogen atoms X, and this structure spreads two-dimensionally. Each of the organic layers is including an organic ammonium halide (X—RNH₃). Examples of the organic-inorganic perovskite compound include a compound represented by the following formula (1).

(RNH₃)ₐM_{b}X_{c} (1)

In the formula, R is a hydrogen atom or an organic group, M is a divalent metal, X is a halogen atom, a is 1 or 2, b is 1, and a, b, and c satisfy the relationship a+2b=c. That is, c is 3 when a is 1, and c is 4 when a is 2.

For the organic-inorganic perovskite compound represented by the formula (1), examples of the organic group R include: alkyl groups, such as methyl, ethyl, propyl, isopropyl, butyl, tert-butyl, pentyl, and hexyl; cycloalkyl groups, such as cyclopropyl, cyclopentyl, and cyclohexyl; alkenyl groups, such as vinyl, allyl, butenyl, and hexenyl; alkynyl groups, such as ethinyl, butynyl, and hexynyl: aryl groups, such as phenyl; heteroaryl groups, which include groups exclusively of one or more aromatic heterocyclic rings and groups of a fused heterocyclic ring in which one or more different rings (e.g., aromatic rings, aliphatic rings, and heterocyclic rings) are fused with one or more aromatic heterocyclic rings; formimidoyl (HC(═NH)—); acetimidoyl (CH₃C(═HN)—) ; and propionimidoyl (CH₃CH₂C(═HN)—). Any of the organic groups R may have a substituent group, examples of which include, but are not limited to, alkyl groups, cycloalkyl groups, alkenyl groups, alkynyl groups, aryl groups, heterocyclic ring groups, alkoxy groups, alkylthio groups, amino groups, alkylamino groups, arylamino groups, acyl groups, alkoxycarbonyl groups, aryloxycarbonyl groups, acylamino groups, sulfonamide groups, carbamoyl groups, sulfamoyl groups, halogen atoms, cyano groups, hydroxy groups, and carboxy groups. Among these, methyl is preferred.

For the organic-inorganic perovskite compound represented by the formula (1), examples of the divalent metal include cadmium (Ca), strontium (Sr), cadmium (Cd), copper (Cu), nickel (Ni), manganese (Mn), iron (Fe), cobalt (Co), palladium (Pd), germanium (Ge), tin (Sn), lead (Pb), ytterbium (Yb) europium (Eu), and indium (In). Among these, Pb is preferred.

For the organic-inorganic perovskite compound represented by the formula (1), examples of the halogen atom X include fluorine (F), chlorine (Cl), bromine (Br), iodine (I), astatine (At), and ununseptium (Uus). Among these, Cl, Br, and I are preferred.

Specific examples of the organic-inorganic perovskite compound include CH₃NH₃PbI₃, CH₃NH₃PbBr₃, CH₃NH₃PbBr₂Cl, CH₃NH₃PbCl₃, CH₃NH₃PbBrCl₂, (CH₃(CH₂)ₙCHCH₃NH₃)₂PbI₄ where n=5 to 8, (C₆H₅C₂H₄NH₃)₂PbBr₄, (C₂H₅NH₃)₂PbI₄, (CH₂═CHNH₃)₂PbI₄, (CHCNH₃)₂PbI₄, (n-C₃H₇NH₃)₂PbI₄, (n-C₄H₉NH₃)₂PbI₄, (C₆H₅NH₃)₂PbI₄, (C₆H₃F₂NH₃)₂PbI₄, (C₆F₅NH₃)₂PbI₄, (C₄H₃SNH₃)₂PbI₄.

As described above, the organic-inorganic perovskite compound is a hybrid compound produced by a reaction between an organic compound and an inorganic compound. In this embodiment, methylammonium halide (X—CH₃NH₃) is used as the organic compound, and lead halide (PbXₐ where X=Cl and/or Br, a=1 or 2) is used as the inorganic compound. That is, the organic-inorganic perovskite compound is preferably CH₃NH₃PbBr₃, CH₃NH₃PbBr₂Cl, CH₃NH₃PbCl₃, or CH₃NH₃PbBrCl₂ because these compounds have the photoelectric conversion function and do not interfere with the transparency of the substrate 11.

With regard to the organic-inorganic perovskite compound, the color of the organic-inorganic perovskite compound can be varied in accordance with the halogen species in the lead halide. Thus, the color of the photoelectric conversion layer 14 can be varied in accordance with the wavelength range of the light source. This results in improvement in the photoelectric conversion efficiency of the photoelectric conversion element 10. It is also possible to vary the color of the organic-inorganic perovskite compound in accordance with the decoration of the external case 2.

For example, when the wavelength of the light source is in the ultraviolet range, a colorless transparent organic-inorganic perovskite compound may be used. Examples of the compound include Cl-containing compounds such as CH₃NH₃PbCl₃. Transparent organic-inorganic perovskite compounds do not interfere with the decorative properties of the watch 1 and thus provides high decorative design flexibility for the watch 1. On the other hand, when the wavelength of the light source is in the visible range, a colored transparent organic-inorganic perovskite compound may be used. Examples of the compound include Br-containing compounds such as CH₃NH₃PbBr₃, which exhibits orange color, and CH₃NH₃PbBr₂Cl and CH₃NH₃PbBrCl₂, which exhibit yellow color. Furthermore, the colored transparent organic-inorganic perovskite compound can be appropriately selected in accordance with the decoration of the external case 2. This results in improved decorative properties of the watch 1.

The photoelectric conversion element 10 may be configured to be able to operate on any wavelength in the visible range or the ultraviolet range in sunlight. Specifically, the configuration may be as follows, for example. The organic-inorganic perovskite compound may be a laminate including a colorless transparent organic-inorganic perovskite compound and a colored transparent organic-inorganic perovskite compound, or the photoelectric conversion layer 14 may include a region that operates on visible light and a region that operates on ultraviolet light that are appropriately disposed. Thus, the photoelectric conversion layer 14 can operate on a wide range of wavelengths. With this configuration, the photoelectric conversion efficiency of the photoelectric conversion element 10 is further improved. The organic-inorganic perovskite compounds can be used in any combination depending on the associated wavelength range and decoration.

The hole transport layer 15 is disposed between the photoelectric conversion layer 14 and the second electrode 16 and has the function of blocking the transport of the charges (electrons) opposite to the charges (holes) that the hole transport layer 15 mainly transports. That is, the hole transport layer 15 is configured to prevent migration of the electrons to the second electrode 16 (cathode) so that the holes generated in the photoelectric conversion layer 14 can be efficiently migrated to the second electrode 16. If the hole transport layer 15 does not have the function of blocking transport of the electrons, migration of the electrons and holes to the second electrode 16 via the hole transport layer 15 will occur, and as a result, deactivation due to recombination of the electrons and holes will occur. Thus, because of the function of blocking the transport of electrons as described above, the hole transport layer 15 inhibits deactivation due to recombination of the holes and electrons, and this enables efficient transport of the holes to the second electrode 16.

Examples of the material for forming the hole transport layer 15 include electrically conductive polymers such as poly(3,4-ethylenedioxythiophene)-poly(styrene sulfonate) (PEDOT-PSS), poly(3-hexylthiophene-2,5-diyl) (P3HT), polytriallylamine (PTAA), tetrathiafulvalene (TTF-1), and polythiophene (PT). The “PEDOT-PSS” may be used as follows. PEDOT molecules, which provide carrier (charge) transport paths, and PSS molecules, which act as acceptors, are mixed with water, and the aqueous solution is applied by, for example, spin coating so that a homogeneous amorphous thin film, which forms the hole transport layer 15, can be obtained. Examples of the material further include transparent materials such as copper halide, e.g., copper (I) iodide (CuI). In this embodiment, the material (electrically conductive polymer) for forming the above-described electron transport layer 13 may be employed. In this embodiment, transparent materials such as CuI are preferred because they are capable of transporting holes and do not interfere with the transparency of the substrate 11. The average thickness of the hole transport layer 15 is not particularly limited, but preferably, it is less than or equal to 100 nm, and particularly preferably ranges from greater than or equal to 10 nm to less than or equal to 80 nm.

The second electrode 16 is disposed on the hole transport layer 15 and may be formed from any electrically conductive material provided that it is transparent and electrically conductive. The second electrode 16 may include an insulating material provided that the transparency is maintained and a layer including an electrically conductive material is disposed at the side facing the hole transport layer 15. It is preferable that the second electrode 16 form good contact with the hole transport layer 15, have a work function that is not significantly different from the work function of the hole transport layer 15, and be chemically stable. The definition of the term “transparent” is as described above.

The material, shape, structure, thickness, electrical conductivity, and other properties of the second electrode 16 may be selected as appropriate from among those of known electrodes. For example, a transparent electrode material that can be used to form the first electrode 12 may be used. Another example of the configuration may be as follows. A thin film is formed from a known electrode material and a layer of transparent electrode material is disposed on the thin film. Examples of the known electrode material include noble metals, such as silver (Ag), platinum (Pt), and iridium (Ir), and electrically conductive oxides, typified by, for example, lanthanum nickel oxide (LNO).

Furthermore, the material of the second electrode 16 needs to have both transparency and electrical conductivity. For this purpose, nanowires of predetermined metal may be joined together at the intersection points to obtain a transparent metal electrode to be used. The transparent metal electrode can be formed by depositing metal nanowires on the hole transport layer 15 and irradiating them with pulsed light to join together the metal nanowires at the intersection points.

As used herein, pulsed light refers to light emitted for a short emission period (emission time), and in the case where light emission is performed more than one time, pulsed light refers to light emission having, between a first emission period (on) and a second emission period (on), a period during which no light is emitted (emission intermission (off)). It is preferable that the pulsed light be emitted by a light source including a flash lamp, e.g., a xenon flash lamp. Also, it is preferable that the pulse width range from greater than or equal to 20 microseconds to less than or equal to 50 milliseconds. If the pulse width is less than 20 microseconds, sintering will not proceed, which will decrease the effect of improving the performance of the second electrode 16. If the pulse width is longer than 50 milliseconds, it may have an adverse effect on the hole transport layer 15 due to photodegradation and thermal degradation, and the metal nanowires will be easily blown off.

The metal nanowires refer to nanometer-scale particles including metal and having a rod shape or a thread shape. That is, the metal nanowires refer to metals having a diameter on the order of nanometers. The metal nanowires include metal nanotubes, porous or non-porous, having a tubular shape (hollow at the center).

Examples of the material of the metal nanowires include, but are not limited to, Fe, Co, Ni, Cu, zinc (Zn), ruthenium (Ru), rhodium (Rh), Pd, Ag, Cd, osmium (Os), Ir, Pt, and Au. Cu, Ag, Pt, and Au are preferable because they have high electrical conductivity, and Ag is more preferable. It is preferable that the diameter of the metal nanowires range from greater than or equal to 10 nm to less than or equal to 300 nm and that the length of the metal nanowires range from greater than or equal to 3 μm to less than or equal to 500 μm. If the diameter is less than 10 nm, the metal nanowires, when joined together, will have insufficient strength. If the diameter is greater than 300 nm, the transparency will decrease. If the length is less than 3 μm, effective overlapping of intersection points will not be achieved. If the length is greater than 500 μm, the electrical conductivity will decrease.

The average thickness of the second electrode 16 is not particularly limited, but preferably, it ranges from greater than or equal to 50 nm to less than or equal to 200 nm, and particularly preferably ranges from greater than or equal to 80 nm to less than or equal to 120 nm. The surface resistance of the second electrode 16 is not particularly limited but preferably is low. Specifically, the surface resistance of the second electrode 16 is preferably less than or equal to 80 Ω/□, and more preferably less than or equal to 20 Ω/□. It is preferable that the lower limit of the surface resistance of the second electrode 16 be as low as possible. Thus, although the lower limit need not be particularly specified, it is preferably greater than or equal to 0.01 Ω/□.

### Method for Producing Solar Cell Device

Next, a method for producing the watch 1, which is a solar cell device, will be described with reference to the drawings. In this embodiment, a method for producing the photoelectric conversion element 10, which is incorporated in the watch 1, will be mainly described. For a method for producing the watch 1, a known method can be employed, and therefore a description of the known method will be omitted as appropriate.

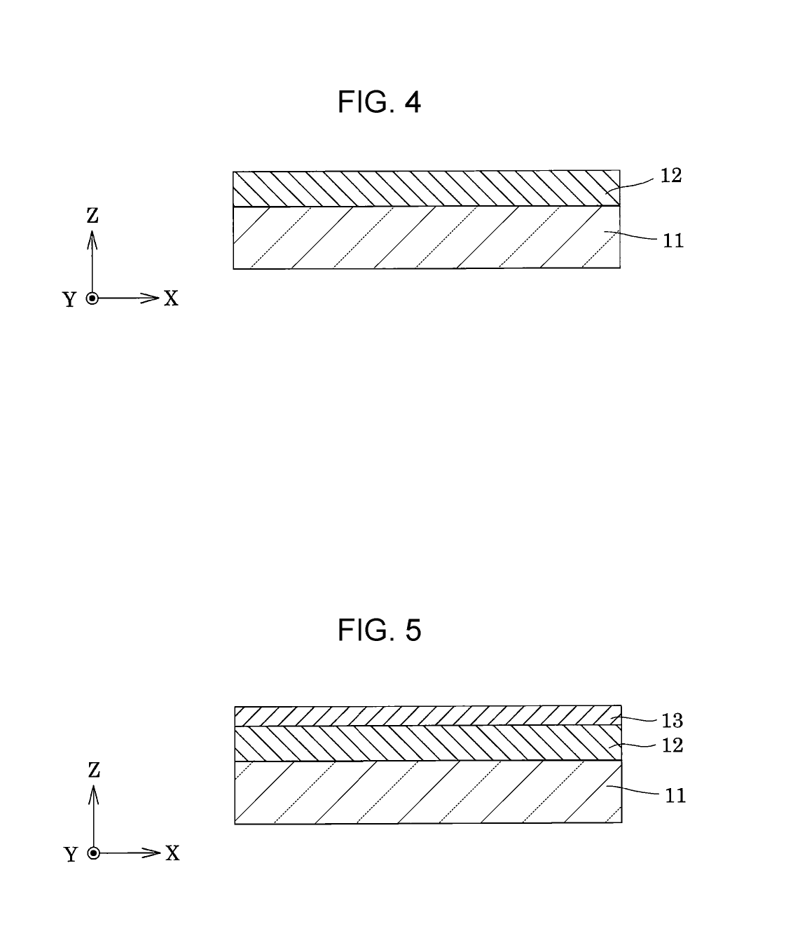

FIGS. 4 to 7 are cross-sectional views illustrating an example of production of the photoelectric conversion element. First, as illustrated in FIG. 4, the substrate 11, which may be a transparent substrate or a transparent film, for example, is prepared and, on the substrate 11, a transparent electrode film including a transparent electrode material, such as ITO or FTO, is formed using a forming technique. Example of the technique include known vapor deposition techniques, such as resistive heating evaporation, electron beam evaporation, and molecular beam epitaxy, and physical vapor deposition (PVD) techniques, such as ion plating, ion beam deposition, and sputtering. The transparent films are stacked one on top of another to form the first electrode 12 having a predetermined thickness.

Next, as illustrated in FIG. 5, the electron transport layer 13, which is including a predetermined material, is formed on the first electrode 12. Examples of the process for forming the electron transport layer 13 include, but are not limited to, known coating processes such as spin coating, gravure coating, bar coating, screen printing, spray coating, dip coating, and die coating. In the case where spin coating is employed, for example, the process may be performed in the following manner to obtain the electron transport layer 13 having a predetermined thickness. In an atmosphere of inert gas, such as N₂ gas or Ar gas, a precursor solution for the electron transport layer 13 is applied by spin coating at revolutions ranging from 1500 rpm to 3000 rpm for a time period ranging from 10 seconds to 30 seconds to deposit the coating film. Subsequently, drying is performed at a predetermined temperature, e.g., room temperature (25° C.), for a time period ranging from 10 minutes to 30 minutes.

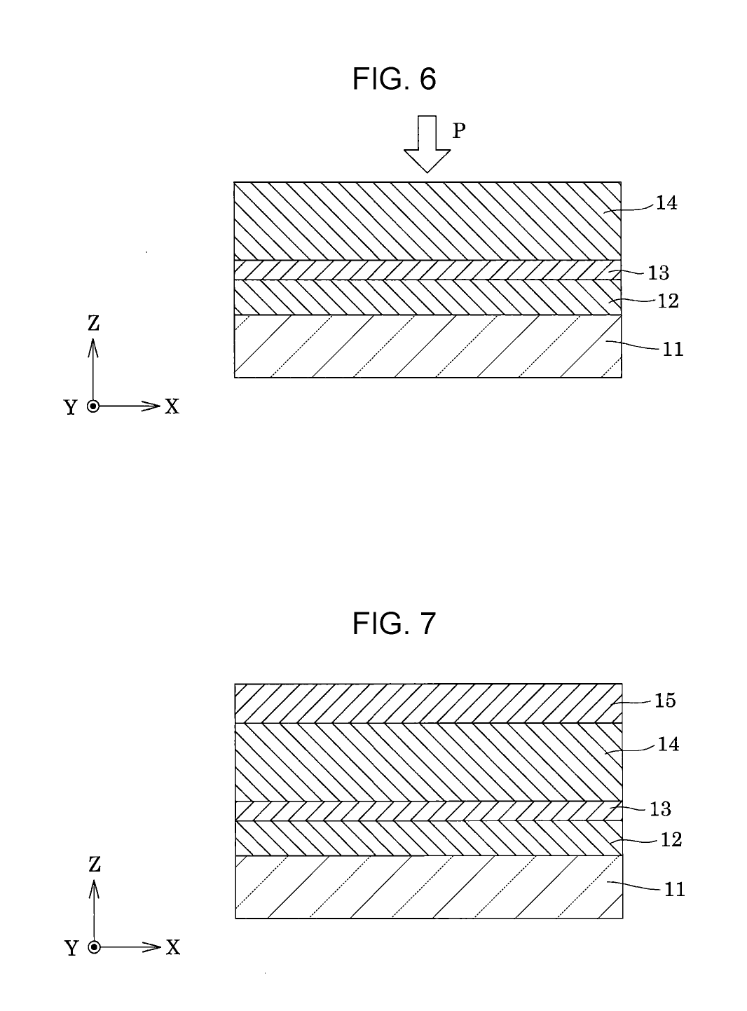

Next, as illustrated in FIG. 6, the photoelectric conversion layer 14, which is including a colorless transparent organic-inorganic perovskite compound and/or a colored transparent organic-inorganic perovskite compound, is formed on the electron transport layer 13. The process for forming the photoelectric conversion layer 14 is not limited, and any of the known coating processes mentioned above may be employed to form the photoelectric conversion layer 14. In the case where spin coating is employed, for example, the process may be performed in the following manner to obtain an organic-inorganic perovskite compound layer having a predetermined thickness. A precursor solution for the photoelectric conversion layer 14 (at a concentration of 40.0 wt %, for example) is obtained by mixing lead halide and methylammonium halide, which is an organic ammonium halide, with a solvent such as N,N-dimethylformamide (DMF). The precursor solution is applied by spin coating at revolutions ranging from 1500 rpm to 3000 rpm for a time period ranging from 10 seconds to 30 seconds to deposit the coating film. Subsequently, drying is performed at a temperature ranging from 70° C. to 130° C. for a predetermined time period, e.g., 10 minutes.

Another process for obtaining an organic-inorganic perovskite compound layer having a predetermined thickness may be as follows. In an inert gas atmosphere, such as described above, a layer including lead halide is formed by, for example, a vacuum deposition method, and on the layer, a layer of methylammonium halide is formed by a mist deposition method. Then, annealing is performed at a predetermined temperature, e.g., 100° C., for a predetermined time period, e.g., 30 minutes. The organic-inorganic perovskite compound layer obtained by this process has higher transparency than the organic-inorganic perovskite compound layer formed by using the precursor solution described above, and thus, for example, can be employed for a high-quality watch, for example.

Thereafter, as necessary, annealing under pressure (pressure annealing) may be performed in an atmosphere of inert gas, such as described above, at a temperature ranging from 70° C. to 130° C. for a time period ranging from 10 minutes to 30 minutes while applying a pressure ranging from 0.1 Pa to 10 Pa in the direction of an arrow P in FIG. 6. Such pressure annealing results in formation of a dense organic-inorganic perovskite compound layer and also good adhesion between the first electrode 12, the electron transport layer 13, and the organic-inorganic perovskite compound layer on the substrate 11. As a result, the photoelectric conversion efficiency of the photoelectric conversion element 10 is improved. Thereafter, cooling is performed to obtain an organic-inorganic perovskite-structured thin film (photoelectric conversion layer 14) having a predetermined thickness. The precursor solution may include an additive for stabilizing dispersion of the materials and may also include one or more additives as necessary. The drying time and the pressure annealing time may be appropriately adjusted as necessary.

Next, as illustrated in FIG. 7, the hole transport layer 15 including a predetermined material is formed on the photoelectric conversion layer 14. The process for forming the hole transport layer 15 is not limited and, for example, any of the known coating processes that may be employed to form the above-described electron transport layer 13 may be employed to obtain the hole transport layer 15 having a predetermined thickness.

Examples of the apparatus for drying and annealing the coating films include rapid thermal annealing (RTA) apparatuses, which perform heating by irradiation using an infrared lamp, and hot plates.

Next, on the hole transport layer 15, an electrode film is formed using the deposition process described above, to a thickness ranging from 6 nm to 12 nm. The electrode film is including any of the metal materials that can be used as the material of the metal nanowires. Then, on the electrode film, a transparent electrode film of transparent electrode material, such as ITO or FTO, is formed to a thickness ranging from 5 nm to 10 nm. In this manner, the second electrode 16 is formed.

Another method may be employed to form the second electrode 16. For example, metal nanowires synthesized using a known process are deposited on the hole transport layer 15, and the metal nanowires are irradiated with pulsed light to be joined together at the intersection points. As used herein, the term “joining” means that, at the intersection points of the metal nanowires, the metal material absorbs emitted pulsed light and internal heat generation occurs more efficiently at the intersecting regions so that the regions are welded together. As a result of the joining, the area of connection between the metal nanowires at the intersecting regions increases so that the surface resistance can be reduced. In this manner, the metal nanowires are joined together at the intersection points by irradiation with pulsed light, so that the metal nanowires form a network structure that forms the transparent metal electrode (second electrode 16 having a predetermined thickness). Thus, the photoelectric conversion element 10, illustrated in FIG. 3, is obtained.

The process for depositing the metal nanowires on the hole transport layer 15 is not particularly limited and, for example, a wet coating process using a metal nanowire dispersion liquid may be employed. Examples of the wet coating process include spray coating, bar coating, roll coating, die coating, ink jet coating, screen coating, dip coating, drop coating, relief printing, intaglio printing, and gravure printing.

Examples of the dispersion medium used for the wet coating include ketone compounds, such as acetone, methyl ethyl ketone, and cyclohexanone; ester compounds, such as methyl acetate, ethyl acetate, butyl acetate, ethyl lactate, and methoxyethyl acetate; ether compounds, such as diethyl ether, ethylene glycol dimethyl ether, ethyl cellosolve, butyl cellosolve, phenyl cellosolve, and dioxane; aromatic compounds, such as toluene and xylene; aliphatic compounds, such as pentane and hexane; halogenated hydrocarbons, such as methylene chloride, chlorobenzene, and chloroform; alcohol compounds, such as methanol, ethanol, n-propanol, isopropanol, 1-methoxy-2-propanol (PGME), ethylene glycol, diethylene glycol, triethylene glycol, dipropylene glycol, terpineol, glycerin, diglycerin, bornyl cyclohexanol, bornyl phenol, isobornyl cyclohexanol, and isobornyl phenol; water; and mixed solvents thereof.

The metal nanowire dispersion liquid may optionally contain one or more additional components within a range not to impair the properties of the liquid. Examples of the additional components include binder resins, corrosion inhibitors, adhesion promoters, and surfactants. Application of the dispersion liquid, when it contains a binder resin, results in improved adhesion between the metal nanowires and the hole transport layer 15 when irradiated with light. Examples of the polymer that can be used as the binder resin include thermosetting and thermoplastic resins, example of which include: poly-N-vinyl compounds, such as poly-N-vinylpyrrolidone and poly-N-vinylcaprolactam; polyalkylene glycol compounds, such as polyethylene glycol, polypropylene glycol, polytetrahydrofuran (TFT); polyurethane; cellulose compounds and derivatives thereof; epoxy compounds; polyester compounds; chlorinated polyolefins; and polyacrylic compounds.

Next, the obtained photoelectric conversion element 10 is joined to the cover glass 4 and the opening 2a of the external case 2 is sealed by the cover glass 4. In the external case 2, components such as the hands 6, the clock face 3, and the movement 7 have been incorporated. The band 5 is attached to the external case 2. In this manner, the watch 1 illustrated in FIG. 1 is produced.

### EXAMPLES

In the following, the invention will be described more specifically with examples. The invention is not limited to the examples below.

### Example 1

In Example 1, the above-described photoelectric conversion element 10 of the first embodiment was produced. The first electrode 12 was formed from FTO. Specifically, the photoelectric conversion element 10 of Example 1 was made up of the substrate 11, the first electrode 12, the electron transport layer 13, the photoelectric conversion layer 14, the hole transport layer 15, and the second electrode 16, which were sequentially stacked.

First, a transparent electrode (first electrode 12) including FTO was formed on a glass substrate (substrate 11) to obtain an FTO electrode substrate. Next, a titanium (IV) chloride (TiCl₄) solution at a concentration ranging from 0.1 M to 0.3 M was applied to the FTO electrode substrate by spraying and this was subjected to firing at temperatures ranging from 450° C. to 550° C. Thus, a dense layer (TiO₂ layer) (electron transport layer 13) including titanium oxide (TiO₂) and having a thickness ranging from 20 nm to 80 nm were formed. Next, in an atmosphere of N₂ gas, lead chloride (II) (PbCl₂) was deposited on the TiO₂ layer to a thickness ranging from 100 nm to 150 nm by vacuum deposition, and methyl ammonium chloride (CH₃NH₃Cl) was applied thereto to a thickness ranging from 100 nm to 150 nm by mist deposition. This was subjected to annealing at 100° C. for 30 minutes. Thus, a CH₃NH₃PbCl₃ layer (photoelectric conversion layer 14) that is organic-inorganic perovskite-structured and has a thickness ranging from 150 nm to 300 nm was formed. This was cooled, and thereafter a copper (I) iodide (CuI) solution was applied to the CH₃NH₃PbCl₃ layer by spin coating. Thus, a CuI layer (hole transport layer 15) having a thickness ranging from 10 nm to 80 nm was formed. This was dried at room temperature (25° C.), and thereafter a Ag nanowire ink was applied to the CuI layer by spin coating. Thus, a transparent metal electrode (second electrode 16) including Ag nanowires was formed. In this manner, the photoelectric conversion element 10 was produced.

### Example 2

The photoelectric conversion element 10 was produced in the same manner as in Example 1 except the following differences. A transparent electrode (first electrode 12) including ITO was formed on a glass substrate (substrate 11) to obtain an ITO electrode substrate. A ZnO layer (electron transport layer 13) having a thickness ranging from 20 nm to 80 nm was formed by applying, to the ITO electrode substrate, a dispersion liquid of zinc oxide (ZnO) nanoparticles having a particle size ranging from 10 nm to 25 nm and subjecting this to firing at temperatures ranging from 150° C. to 300° C.

### Example 3

The photoelectric conversion element 10 was produced in the same manner as in Example 1 except the following differences. A porous TiO₂ layer (electron transport layer 13) was formed by applying a precursor solution containing titanium oxide nanoparticles dispersed in an ethanol solvent to the TiO₂ layer and subjecting this to degreasing at 100° C. and then to firing at 450° C. A photoelectric conversion layer 14 including a colorless transparent organic-inorganic perovskite compound was formed by using a precursor solution in which CH₃NH₃PbCl₃ is dissolved in a DMF solvent and drying it at 100° C. A metal electrode (second electrode 16) was formed by forming an electrode film including Ag or Au to a thickness of 6 nm and forming thereon an oxide electrode of ITO to a thickness of 10 nm.

### Example 4

The photoelectric conversion element 10 was produced in the same manner as in Example 3 except that a transparent electrode (first electrode 12) including ITO was formed on a glass substrate (substrate 11).

### Example 5

The photoelectric conversion element 10 was produced in the same manner as in Example 3 except that a photoelectric conversion layer 14 including a transparent orange organic-inorganic perovskite compound was formed by using a precursor solution in which CH₃NH₃PbBr₃ is dissolved in a DMF solvent and drying it at 100° C.

### Example 6

The photoelectric conversion element 10 was produced in the same manner as in Example 5 except that a transparent electrode (first electrode 12) including ITO was formed on a glass substrate (substrate 11).

### Example 7

The photoelectric conversion element 10 was produced in the same manner as in Example 2 except the following differences. A porous TiO₂ layer (electron transport layer 13) was formed by applying a precursor solution containing titanium oxide nanoparticles dispersed in an ethanol solvent to the TiO₂ layer and subjecting this to degreasing at 100° C. and then to firing at 450° C. A photoelectric conversion layer 14 including a transparent yellow organic-inorganic perovskite compound was formed by using a precursor solution in which CH₃NH₃PbBr₃₋ₓClₓ (X=1 or 2) is dissolved in a DMF solvent and drying it at 100° C. A metal electrode (second electrode 16) was formed by forming an electrode film including Ag or Au to a thickness of 6 nm and forming thereon an oxide electrode of ITO to a thickness of 10 nm.

### Example 8

The photoelectric conversion element 10 was produced in the same manner as in Example 7 except that a transparent electrode (first electrode 12) including ITO was formed on a glass substrate (substrate 11).

### Example 9

Each of the photoelectric conversion elements 10 obtained in Examples 1 to 8 was joined to the cover glass 4 and the opening 2a of the external case 2 is sealed by the cover glass 4. In the external case 2, components such as the hands 6, the clock face 3, and the movement 7 had been incorporated. The band 5 was attached to the external case 2. In this manner, the watch 1 illustrated in FIG. 1 was produced in each of the examples.

The watches 1, each of which included one of the photoelectric conversion elements 10 obtained in Examples 1 to 8, were produced in a low temperature process as described above. Thus, the watches 1 allow for convenience, mass productivity, and good cost effectiveness. Furthermore, since the production is carried out through such a process, there is a possibility that the photoelectric conversion element 10 can be used for flexible batteries. Thus, application to solar cell devices other than watches may be possible. Furthermore, since the photoelectric conversion element 10 has transparency, it does not interfere with the decorative properties of solar cell devices.

Furthermore, the watches 1 including one of the photoelectric conversion elements 10 produced in Examples 5 to 8 each include a photoelectric conversion layer 14 including a colored transparent organic-inorganic perovskite compound, and therefore can operate on a wide range of wavelengths. Thus, high photoelectric conversion efficiency is achieved. Furthermore, decoration can be added to the solar cell device by changing colors.

### OTHER EMBODIMENTS

In the watch including the photoelectric conversion element described in the above embodiment, the photoelectric conversion element is formed on the front side of one surface of the cover glass, which is the surface closer to the clock face surface. However, the configuration is not limited to this. For example, the photoelectric conversion element may be divided and the divided portions may be disposed in series. This configuration increases the electromotive force from 1.0 V to 1.1 V and therefore improves the photoelectric conversion efficiency.

In the above-described embodiments, the watch incorporating a photoelectric conversion element is a non-limiting example of a solar cell device. Other examples of solar cell devices that may be used include timepieces such as analog clocks, digital clocks, and smart watches, and wearable devices such as wrist bands having the function of human body sensing.

What is claimed is:

1. A solar cell device including an information display, a protective substrate that protects an information display surface of the information display, and a photoelectric conversion element,
the photoelectric conversion element being disposed on a surface of the protective substrate, the surface facing the information display surface of the information display, the photoelectric conversion element comprising:
a first electrode including a transparent electrode material;
a second electrode including a transparent electrode material;
a photoelectric conversion layer disposed between the first electrode and the second electrode and including an organic-inorganic perovskite compound;
an electron transport layer disposed between the first electrode and the photoelectric conversion layer; and
a hole transport layer disposed between the photoelectric conversion layer and the second electrode.

2. The solar cell device according to claim 1, wherein the organic-inorganic perovskite compound is a compound produced by a reaction between lead halide and organic ammonium halide.

3. The solar cell device according to claim 1, wherein the organic-inorganic perovskite compound is a compound selected from the group consisting of CH₃NH₃PbBr₃, CH₃NH₃PbBr₂Cl, CH₃NH₃PbCl₃, and CH₃NH₃PbBrCl₂.

4. The solar cell device according to claim 1, wherein the photoelectric conversion layer includes a colorless transparent organic-inorganic perovskite compound and a colored transparent organic-inorganic perovskite compound.

5. The solar cell device according to claim 4, wherein the colorless transparent organic-inorganic perovskite compound is CH₃NH₃PbCl₃ and the colored transparent organic-inorganic perovskite compound is a compound selected from the group consisting of CH₃NH₃PbBr₃, CH₃NH₃PbBr₂Cl, and CH₃NH₃PbBrCl₂.

6. The solar cell device according to claim 1, wherein the transparent electrode material of the second electrode is metal nanowires.

7. The solar cell device according to claim 1, wherein the first electrode is disposed on the protective substrate.

8. A method for producing a solar cell device, the method comprising:
forming a photoelectric conversion element by sequentially stacking, on a surface of a protective substrate, a first electrode, an electron transport layer, a photoelectric conversion layer, a hole transport layer, and a second electrode, the protective substrate protecting an information display surface of an information display,
wherein the first electrode includes a transparent electrode material and the second electrode includes a transparent electrode material, and
the photoelectric conversion layer includes an organic-inorganic perovskite compound produced by forming a layer comprising of lead halide and a layer comprising of an organic ammonium halide and heating the layers.
